(19) United States
(12) Patent Application Publication
(10) Pub. No.: US 2014/0179097 A1
(43) Pub. Date: Jun. 26, 2014

(54) DEPOSITION APPARATUS AND METHOD

(71) Applicant: LAM RESEARCH CORPORATION, Fremont, CA (US)

(72) Inventors: Diane J. HYMES, San Jose, CA (US); Stephen M. SIRARD, Austin, TX (US)

(73) Assignee: LAM RESEARCH CORPORATION, Fremont, CA (US)

(21) Appl. No.: 13/725,853

(22) Filed: Dec. 21, 2012

(51) Int. Cl. H01L 21/768

(52) U.S. Cl. CPC H01L 21/76877
USPC 438/610; 118/50

(57) ABSTRACT

A method for filling features in a layer over a substrate is provided. A dispersion of nanoparticles less than 5 nm is placed on the layer. The liquid is frozen by lowering a temperature of the liquid. The frozen liquid is sublimated by decreasing pressure and subsequently heating the frozen liquid, wherein the nanoparticles are not sublimated.

### BACKGROUND OF THE INVENTION

The present invention relates to the formation of semiconductor devices. More specifically, the invention relates to an apparatus or method for depositing materials during the formation of semiconductor devices.

During semiconductor wafer processing, the deposition of materials, such as copper, is used in forming semiconductor devices.

### SUMMARY OF THE INVENTION

To achieve the foregoing and in accordance with the purpose of the present invention, a method for filling features in a layer over a substrate is provided. A dispersion of nanoparticles less than 5 nm diameter is placed on the layer. The liquid is frozen by lowering the temperature of the liquid. The frozen liquid is sublimated by decreasing pressure and subsequently heating the frozen liquid, wherein the nanoparticles are not sublimated.

In another manifestation of the invention, an apparatus for filling features in a layer is provided. A chamber for holding the layer is provided. A chuck supports the layer within the chamber. A motor spins the chuck. A dispenser dispenses a liquid with a dispersion of nanoparticles less than 5 nm diameter on the layer for filling the features. A cooling system cools the liquid on the layer to cause the liquid to freeze. A pressure control system lowers the pressure within the chamber. A heating system heats the frozen liquid at the lower pressure to enable sublimation of the frozen liquid

These and other features of the present invention will be described in more detail below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 is a high level flow chart of an embodiment of the invention.

FIGS. 2A-C are schematic cross sectional views of a stack processed according to an embodiment of the invention.

FIG. 3 is a schematic illustration of a deposition device in an embodiment of the invention.

FIG. 4 illustrates a computer system, which is suitable for implementing a controller used in embodiments of the present invention.

FIG. 5 is a more detailed flow chart of a sublimation step.

FIGS. 6A-C are schematic cross sectional views of a stack processed according to another embodiment of the invention.

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

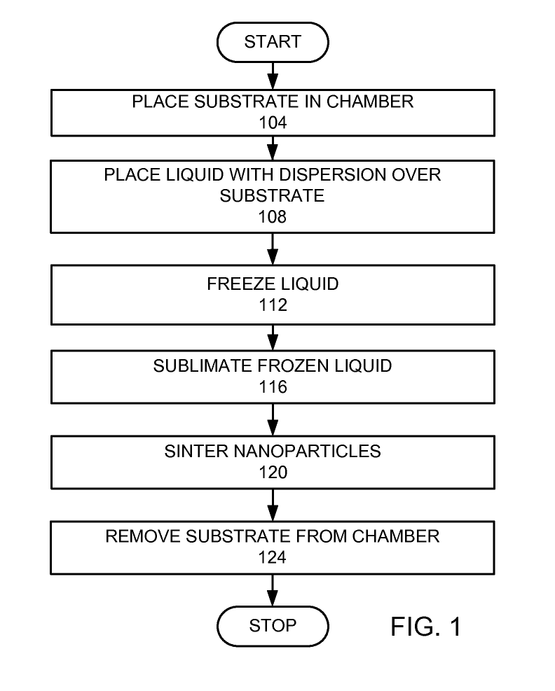

FIG. 1 is a high level flow chart of an embodiment of the invention. A substrate with features is placed in a chamber (step 104). A liquid with a dispersion of nanoparticles is placed over the substrate (step 108). The liquid is frozen (step 112). The frozen liquid is sublimated, without sublimating the nanoparticles (step 116). The nanoparticles are sintered (step 120). The substrate is removed from the chamber (step 124).

### EXAMPLE

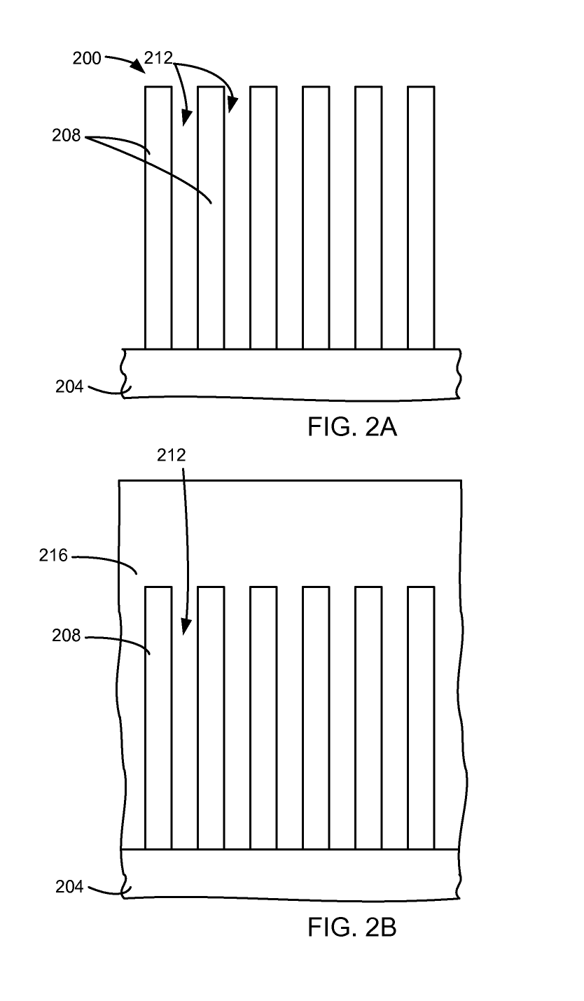

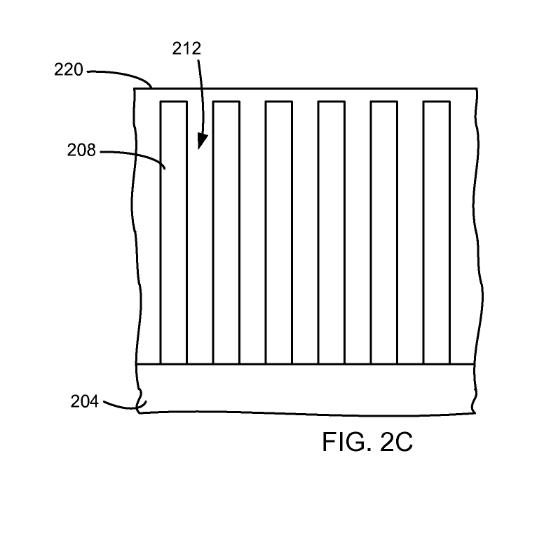

In an example of the invention, a substrate with a dielectric layer with features is provided. FIG. 2A is a cross-sectional view of a stack 200 comprising a substrate 204 over which structures 208 are formed. In this example, the structures 208 are formed from a low-k dielectric layer into which features 212 are etched. The surfaces of these features may contain a layer or multiple layers of conformal thin films. A conventional photoresist lithography, dielectric etch, atomic layer deposition (ALD), chemical vapor deposition (CVD), plasma enhanced chemical vapor deposition (PECVD), and plating may be used to form the structures 208 and features 212.

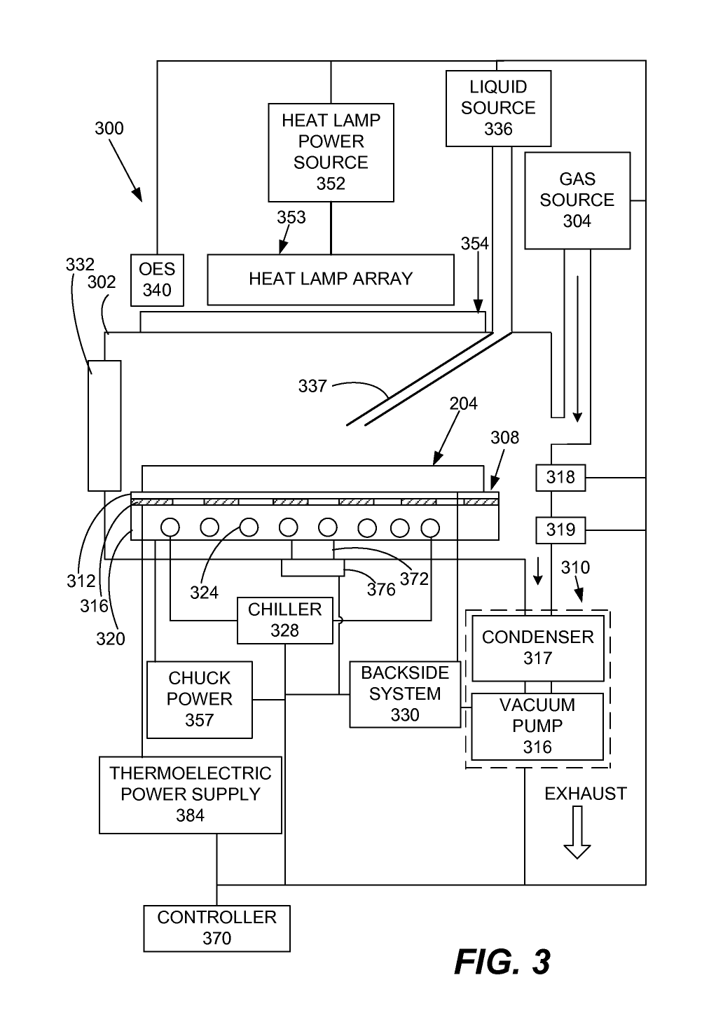

The substrate is placed in a deposition chamber (step 104). FIG. 3 is a schematic view of a deposition system 300 in an embodiment of the invention. The deposition system 300 in this embodiment comprises a deposition chamber 302. A gas source/gas supply mechanism 304 is in fluid connection with the deposition chamber 302. The gas source/gas supply mechanism 304 provides part of an atmosphere control system that controls the pressure and type of gas in the deposition chamber 302. An electrostatic chuck (ESC) 308 is placed in the chamber to support a substrate 204, such as a wafer. The deposition system 300 further comprises a transfer station 332, which provides a method for transferring the wafer into the deposition chamber 302 and provides a vacuum seal through which the atmosphere can be controlled and the deposition process pressure can be achieved, a condenser 317, a vacuum pump 315, a liquid source 336, a liquid dispenser 337, an axle 372, a motor 376, a heat lamp array 353, a heat lamp power source 352, an optical emission spectroscopy (OES) system 340, where the heat lamp array 353 and OES system 340 are adjacent to a window 354 forming one side of the deposition chamber 302.

In this embodiment the ESC 308 comprises a contact layer 312, a layer of thermoelectric devices 316, and a body 320. The body 320 has a plurality of channels 324. The channels 324 are in fluid connection with a chiller 328. The chiller 328 cools and provides a fluid to the channels 324, through which the fluid passes, which cools the body 320 of the ESC 308. A thermoelectric power supply 384 is electrically connected to the layer of thermoelectric devices 316. The thermoelectric power supply 384 provides a current to the thermoelectric devices 316. The thermoelectric power supply 384 uses the magnitude and direction of the current to determine whether the thermoelectric devices 316 provide a heat differential or cooling differential and the magnitude of such a differential between the ESC body 320 and the contact layer 312. A chuck power supply 357 provides a clamping voltage to electrostatically clamp the substrate 204 onto the ESC 308. A backside cooling and heating system 330 is connect to the ESC 308 and provides a fluid, such as helium, through the ESC 308 to the backside of the substrate 204 to increase heat transfer between the ESC 308 and the substrate 204. The backside cooling and heating system 330 is also connected to the vacuum pump 315 which allows for the substrate to be vacuum clamped to the ESC 308.

In this embodiment of the invention, the condenser 317 and the vacuum pump 315 are combined in a cryopump 310 that both provides a vacuum and condenses vapor. A pirani pressure gauge 318 and a capacitance manometer 319 are connected to the deposition chamber 302.

A controller 370 is controllably connected to the thermoelectric power supply 384, the chiller 328, the chuck power supply 357, the cryopump 310, the gas source 304, the liquid source 336, the heat lamp power source 352, the backside cooling and heating system 330, the motor 376, the pirani pressure gauge 318, the capacitance manometer 319, and the OES 340.

The motor 376 is mechanically connected to the ESC 308 through the axel 372. The motor 376 is able to spin the ESC 308.

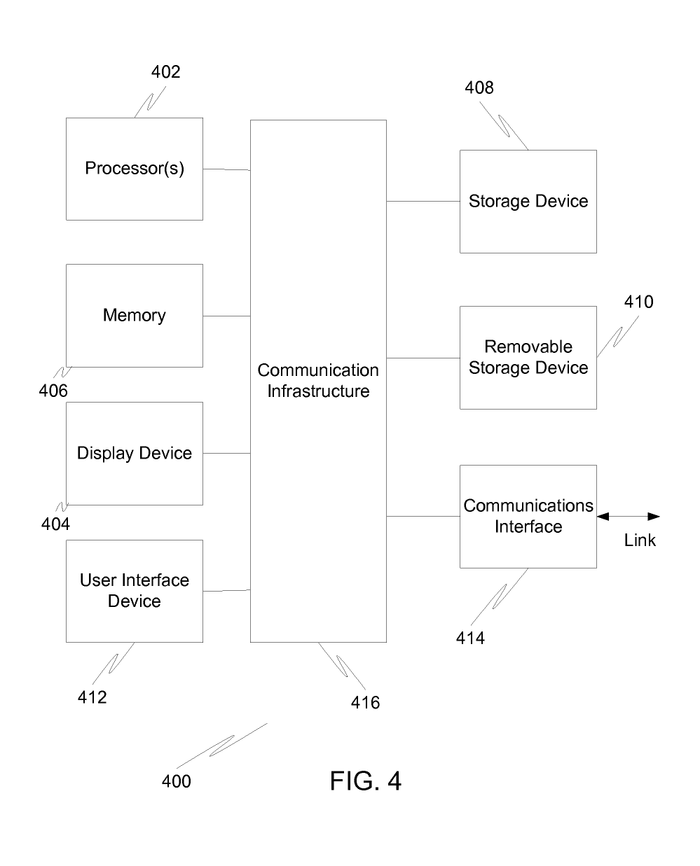

FIG. 4 is a high level block diagram showing a computer system 400, which is suitable for implementing a controller 370 used in embodiments of the present invention. The computer system may have many physical forms ranging from an integrated circuit, a printed circuit board, and a small handheld device up to a huge super computer. The computer system 400 includes one or more processors 402, and further can include an electronic display device 404 (for displaying graphics, text, and other data), a main memory 406 (e.g., random access memory (RAM)), storage device 408 (e.g., hard disk drive), removable storage device 410 (e.g., optical disk drive), user interface devices 412 (e.g., keyboards, touch screens, keypads, mice or other pointing devices, etc.), and a communication interface 414 (e.g., wireless network interface). The communication interface 414 allows software and data to be transferred between the computer system 400 and external devices via a link. The system may also include a communications infrastructure 416 (e.g., a communications bus, cross-over bar, or network) to which the aforementioned devices/modules are connected.

Information transferred via communications interface 414 may be in the form of signals such as electronic, electromagnetic, optical, or other signals capable of being received by communications interface 414, via a communication link that carries signals and may be implemented using wire or cable, fiber optics, a phone line, a cellular phone link, a radio frequency link, and/or other communication channels. With such a communications interface, it is contemplated that the one or more processors 402 might receive information from a network, or might output information to the network in the course of performing the above-described method steps. Furthermore, method embodiments of the present invention may execute solely upon the processors or may execute over a network such as the Internet in conjunction with remote processors that shares a portion of the processing.

The term “non-transient computer readable medium” is used generally to refer to media such as main memory, secondary memory, removable storage, and storage devices, such as hard disks, flash memory, disk drive memory, CD-ROM and other forms of persistent memory and shall not be construed to cover transitory subject matter, such as carrier waves or signals. Examples of computer code include machine code, such as produced by a compiler, and files containing higher level code that are executed by a computer using an interpreter. Computer readable media may also be computer code transmitted by a computer data signal embodied in a carrier wave and representing a sequence of instructions that are executable by a processor.

The chuck power supply 357 provides a chucking voltage to electrostatically clamp the substrate 204 to the ESC 308. A liquid with a dispersion of nanoparticles is placed over the substrate 204 (step 108). In this example, the nanoparticles are copper nanoparticles which are less than 5 nm. The liquid is cyclohexane. Amine coordinating ligands allow the dispersion of the copper nanoparticles within the liquid. The liquid with the dispersion is provided from the liquid source 336 through the liquid dispenser 337 to a top surface of the substrate 204 and structures 208. The motor 376 spins the axle 372, which spins the ESC 308, which spins the substrate 204, causing the liquid to be dispersed over the entire substrate 204. FIG. 2B is a schematic view of a cross-section of the stack 200, over which the liquid 216 has been dispersed.

In this example, a controlled atmosphere is provided in the deposition chamber 302. In this example, an inert, oxygen free or reducing atmosphere is provided by flowing gas into the deposition chamber 302 from the gas source 304. In this example, the gas is nitrogen.

The liquid 216 is frozen (step 112). The chiller 328 is set so that the body 320 of the ESC 308 is cooled to a temperature of <−5° C. In this example, the thermoelectric power supply 384 provides no voltage to the thermoelectric devices 316 to create a temperature differential between the body 320 and the contact layer 312, of 10-20° C. so that the contact layer 312 is cooled to <5° C. The backside cooling and heating system 330 provides a backside gas pressure of helium between the contact layer 312 and the substrate 204 to improve the heat transfer between the contact layer 312 and substrate 204 and improve the temperature uniformity of the substrate 204. The liquid 216 is completely frozen by the cooling from the ESC 308. A fixed hold time may be determined for the freezing process.

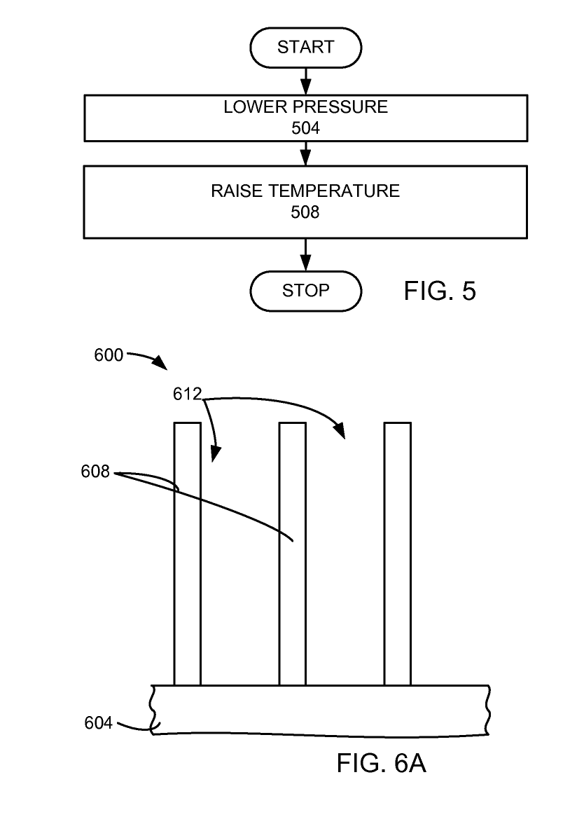

The frozen liquid is sublimated (step 116). FIG. 5 is a more detailed flow chart of the step of sublimating the frozen liquid. To sublimate the frozen liquid, the pressure in the deposition chamber 302 is lowered (step 504). In this example, a cryopump 310 provides a condenser 317 and vacuum pump 315, which is used to pump down the deposition chamber 302 to a reduced pressure between 0.1-1000 mTorr. The substrate 204 is then heated to sublimate the frozen liquid without melting the frozen liquid (step 508). In this example, the heating is provided by changing the temperature differential provided by the thermoelectric devices 316 by applying a current to the thermoelectric devices 316. In this example, the temperature differential is 10° C. so that the contact layer 312 is placed at a temperature of >−5C° C. In this example, the chiller 328 is maintained at a constant temperature and the thermoelectric devices 315 are used to provide additional cooling and/or heating. This allows for a quicker, more efficient, and more precise change in temperature as the temperature of the contact layer 312 cycles between a temperature for freezing the liquid and a temperature for sublimating the liquid in a sublimation process. In this sublimation process, a low pressure is used to sublime the frozen liquid directly to a gas phase by maintaining a pressure below the vapor pressure of the frozen liquid. The condenser 317 reduces the vaporized liquid that reaches the vacuum pump 315 to maintain the efficiency of the vacuum pump 315. Because the sublimation step generates condensable vapor, the condenser 317 is preferred to handle the sublimated liquid.

The OES system 340 may be used to determine when all of the frozen liquid has been sublimated. In the alternative, the sublimation may be performed for a fixed time. In another alternative, the pressure convergence of the Pirani pressure gauge 318 and capacitance manometers 319 may be used to determine when all of the frozen liquid has been sublimated.

FIG. 2C is a cross-sectional view of the stack 200 after the frozen liquid 216 has been sublimated leaving behind a deposition of nanoparticles 220. In this example, the copper nanoparticles 220 form contacts for filling the features 212. In this example, the deposition of nanoparticles 220 are sintered (step 120). In this example, the heat lamp power source 352 provides power to the heat lamp array 353 to heat the deposition of nanoparticles 220 to a temperature of between 100° C. to 200° C. Because the nanoparticles 220 are less than 5 nm in diameter, the sintering is able to occur at the low temperature range of <150° C. to 200° C.

The substrate 204 is removed from the deposition chamber 302 (step 124). During the removal process, the substrate 204 is dechucked by removing the chucking voltage. The pressure in the deposition chamber 302 is returned to atmospheric pressure and the transfer station 332 is opened. Other processes, such as planarization, are provided either before or after the substrate 204 is removed from the chamber 302 to further process the stack 200.

Preferably, all of the nanoparticles in the liquid are less than 5 nm in length or diameter. More generally, most of the nanometer particles in the liquid are less than 5 nm in length or diameter. Preferably, the liquid is organic compounds, organic solvents, organic acids, surfactants, or water. Organic solvents may include tert butanol (TBA). Organic compounds may include cyclohexane.

Other heating and/or cooling systems may be used. Preferably, heating for sintering is from the top, since only the nanoparticles and not the whole substrate need to be heated for sintering. Preferably, the features have a CD of less than 100 nm. More preferably, the features have a CD of less than 50 nm. Most preferably, the features have a CD of less than 10 nm. This example also reduces collapse of thin structures. Preferably, some of the structures have a CD of less than 50 nm. More preferably, the structures have a CD of less than 20 nm.

By using nanoparticles that are less than 5 nm, the dispersion is able to fill features with a CD of less than 50 nm. In addition, such nanoparticles may be sintered at a temperature low enough to prevent damage to the semiconductor device. The freezing and sublimation of the liquid prevents pattern collapse and is able to remove liquid and ligand residue, without removing the nanoparticles. Preferably, the liquid and ligand residue is less than 10 ppm. By eliminating the vapor-liquid interface an embodiment of the invention eliminates capillary forces that cause the collapse of features.

### Alternative Embodiments

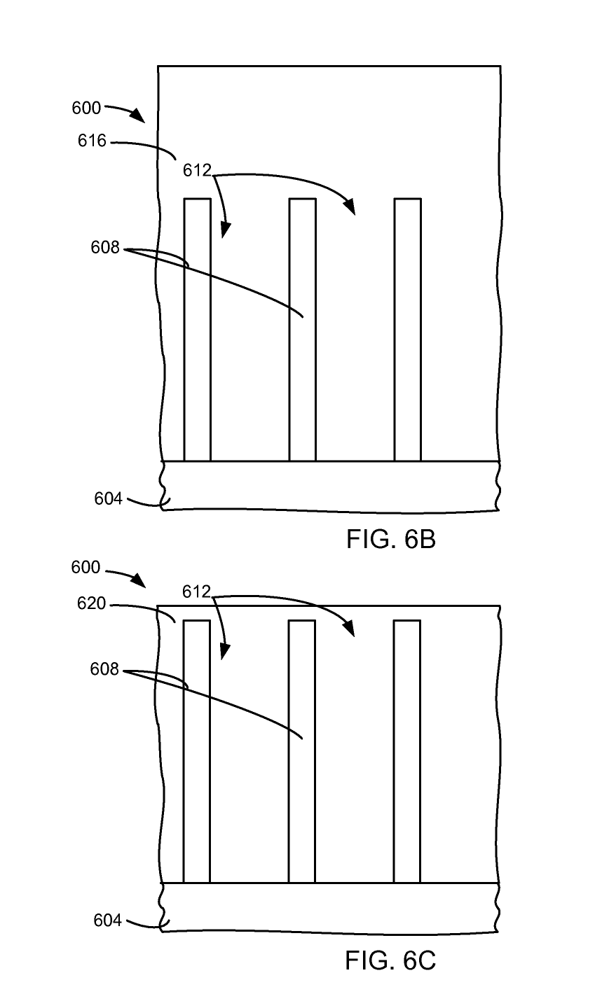

Various alternative embodiments of the invention the nanoparticles are a dielectric material. In such an embodiment thin metal structures may be formed and used for contacts. A dielectric layer may then be deposited around the metal structures. FIG. 6A is a schematic cross-sectional view of a stack 600 with structures 608 and features 612 between the structures 608 over a substrate 604. In this example, the structures 608 are free standing copper contacts formed in a sacrificial layer that has been removed, leaving the free standing copper contact structures 608. The substrate 604 is placed in a deposition chamber (step 104). A liquid with a dispersion is place over the substrate 604 (step 106). FIG. 6B is a schematic cross-sectional view of the stack 600 with a liquid 616 placed over the substrate 604 and structures 608. The liquid 616 is frozen (step 112) and then sublimated (step 116). In this example, a plurality of cycles of placing the liquid over the substrate (108), freezing the liquid (step 112), and sublimating the frozen liquid (step 116) may be used to provide the desired amount of nanoparticles. When the deposition is completed, the substrate 604 is removed from the chamber (step 124). In this example, sintering is not needed. FIG. 6C is a schematic cross-sectional view of the stack 600 after the nanoparticles 620 of a dielectric material have filled the features 612 over the substrate 604.

In another embodiment, the nanoparticles may be nanoparticles for forming a sacrificial layer, which is subsequently removed. For example, carbon nanoparticles may be used to form a sacrificial layer that is removed by ashing.

In another embodiment, the nanoparticles are different types of material. For example, some nanoparticles may be copper and other nanoparticles may be tin. The resulting contacts would then be a copper tin alloy. In another embodiment, the nanoparticles may be silicon oxide and an organic material to form a low-k dielectric.

In other embodiments of the invention, other liquids may be used. Some of the alternative chemistries may be, but are not limited to, Dimethyl sulfoxide (DSMO), TBA, acetic acid, carbon tetrachloride, isopropanol, dimethyl carbonate, water and mixtures thereof. In an embodiment using (DSMO), where the deposition liquid does not comprise water the controlled atmosphere may have a low humidity. Such deposition liquids may be a pure liquid or a mixture of two or more liquids.

In another embodiment the controlled atmosphere may be any inert gas that contains a low percentage or is free of moisture. Certain inert gases, such as Ar, may have advantages for electrostatically chucking/dechucking the wafers from the ESC. It is believed that if the atmosphere is not controlled, oxygen will be absorbed into the deposition liquid.

Various different devices may be used to achieve chamber vacuum, such as, a mechanical pump and/or a turbo molecular pump. An inert gas, such as Ar, He, or N₂, may be supplied to the chamber at a controlled flow rate to maintain the desired chamber pressure. In an alternative embodiment, no gas is supplied to maintain desired chamber pressure. Preferably, the chamber pressure is maintained at <5 mTorr during sublimation. For backside cooling or heating, an inert gas, such as but not limited to He or Ar, is supplied to the backside of the electrostatically chucked wafer at a pressure preferably in the range of 1 Ton—40 Torr in order to provide uniform and efficient heat transfer to the wafer.

In alternative embodiments, the heating of the substrate may be accomplished by changing the chiller set point on the ESC, or by providing a second chiller at a higher temperature and provided fluid from the second chiller, or changing the temperature differential provided by the thermoelectric units, or by providing heat from the heat lamp array. Lifting pins may be used to raise the substrate off of the chuck before the substrate is heated with the heating lamps.

The wafer is held at the desired chamber pressure and temperature until the endpoint of the sublimation step is detected. In one embodiment, the endpoint can be detected by the use of a capacitance gauge and a pirani pressure gauge. These gauges will read differently when liquid vapor is in the chamber, but will converge to the same value when the sublimation endpoint occurs. Alternative methods for detecting sublimation endpoint also could include isolating the chamber from the vacuum pumps and checking the leak rate of the chamber, which is expected to be much higher if vapor is being generated from the wafer.

In various embodiments, during the removal of the substrate, the chamber pressure is increased to 760 Torr by the introduction of an inert gas, such as but not limited to N2, Ar, or He. The wafer is discharged from the ESC and any wafer backside gas flow is shut off. The wafer is then removed from the chamber. In one embodiment a plasma from an inert gas energized with RF power may be used to discharge the wafer from the ESC. The wafer may be discharged before, simultaneously, or after the chamber pressure has been increased to atmospheric pressure. In another embodiment, the wafer may be moved to another chamber for plasma treatment.

In another embodiment of the invention, a plurality of ESCs with each ESC holding a substrate so that a plurality of substrates is processed at the same time is in a single deposition chamber. The ESCs may be in a single plane or may be stacked.

While this invention has been described in terms of several preferred embodiments, there are alterations, permutations, and various substitute equivalents, which fall within the scope of this invention. It should also be noted that there are many alternative ways of implementing the methods and apparatuses of the present invention. It is therefore intended that the following appended claims be interpreted as including all such alterations, permutations, and various substitute equivalents as fall within the true spirit and scope of the present invention.

1. A method for filling features in a layer over a substrate, comprising:
placing on the layer a liquid with a dispersion of nanoparticles less than 5 nm;
freezing the liquid by lowering a temperature of the liquid; and
sublimating the frozen liquid by decreasing pressure and subsequently heating the frozen liquid, wherein the nanoparticles are not sublimated.

2. The method, as recited in claim 1, wherein the nanoparticles are attached to ligands.

3. The method, as recited in claim 2, wherein the sublimating the liquid also sublimates the ligands.

4. The method, as recited in claim 3, wherein the nanoparticles comprise metal.

5. The method, as recited in claim 4, further comprising sintering the nanoparticles.

6. The method, as recited in claim 5, wherein the placing on the layer a liquid, comprises:
dispensing the liquid on the layer; and
spinning the substrate.

7. The method, as recited in claim 6, wherein the liquid comprises at least one of an organic compound such as an organic acid, a surfactant, water, an organic solvent, or TBA.

8. The method, as recited in claim 7, wherein at least one of the features has a CD (critical dimension) of less than 100 nm.

9. The method, as recited in claim 8, wherein the nanoparticles comprise a first plurality of nanoparticles of a first metal and a second plurality of nanoparticles of a metal of a second metal different from the first metal.

10. The method, as recited in claim 1, wherein the nanoparticles are dielectric or carbon based.

11. The method, as recited in claim 10, wherein the features define a structure with a CD (critical dimension) of less than 50 nm.

12. The method, as recited in claim 1, wherein the sublimation leaves less than 10 ppm of residue.

13. The method, as recited in claim 1, wherein the placing on the layer a liquid, comprises:
dispensing the liquid on the layer; and
spinning the substrate.

14. The method, as recited in claim 1, wherein the liquid comprises at least one of an organic compound such as an organic acid, a surfactant, water, an organic solvent, or TBA.

15. The method, as recited in claim 1, wherein the nanoparticles comprise metal.

16. The method, as recited in claim 15, further comprising sintering the nanoparticles.

17. An apparatus for filling features in a layer, comprising:
a chamber for holding the layer;
a chuck for supporting the layer within the chamber;
a motor for spinning the chuck;
a dispenser for dispensing a liquid with a dispersion of nanoparticles less than 5 nm on the layer for filling the features;
a cooling system for cooling the liquid on the layer to cause the liquid to freeze;
a pressure control system for lowering pressure within the chamber; and
a heating system for heating the frozen liquid at the lower pressure to enable sublimation of the frozen liquid.

18. The apparatus, as recited in claim 17, further comprising a heating system for heating the layer to sinter the nanoparticles.
